(19) United States
(12) Patent Application Publication
(10) Pub. No.: US 2024/0258445 A1
(43) Pub. Date: Aug. 1, 2024

(54) OPTICAL SENSOR USING FERROELECTRICS AND METHOD FOR MANUFACTURING THE SAME

(71) Applicant: KOREA ADVANCED INSTITUTE OF SCIENCE AND TECHNOLOGY, Daejeon (KR)

(72) Inventors: Sung-Yool Choi, Daejeon (KR); Hyeok Jun Jin, Daejeon (KR); Khang June Lee, Daejeon (KR)

(21) Appl. No.: 18/034,591

(22) PCT Filed: Oct. 30, 2020
(86) PCT No.: PCT/KR2020/015003

§ 371 Date: Oct. 23, 2023

(30) Foreign Application Priority Data
Oct. 29, 2020 (KR) 10-2020-0142477

(51) Int. Cl. H01L 31/032; H01L 31/109; H01L 31/18

(52) U.S. Cl. CPC H01L 31/032; H01L 31/109; H01L 31/18

(57) ABSTRACT

The present invention relates to an optical sensor using ferroelectrics, including a substrate; a first type semiconductor stacked on the substrate; and a second type semiconductor in contact with the first type semiconductor to form a heterojunction structure, wherein at least one of the first type semiconductor or the second type semiconductor is ferroelectrics.

### TECHNICAL FIELD

The present disclosure relates to an optical sensor using ferroelectrics and a method for manufacturing the same, and more particularly, to an optical sensor using ferroelectrics with high photoresponsivity and fast response speed and a method for manufacturing the same.

### BACKGROUND ART

Currently, materials such as silicon or gallium arsenide on the market have fast response speed but low photoresponsivity, and 2-dimensional (2D) material based optical sensors reported to date have generally high photoresponsivity, but long response time of a few seconds.

To solve the problem of silicon based optical sensors, Korean Patent No. 10-1539671 discloses optical sensor technology using 2D materials such as graphene.

However, there is not yet any technology related to an optical sensor having a structure for achieving high photoresponsivity and fast response speed and a method for manufacturing the same.

### DISCLOSURE OF THE INVENTION

### Technical Problem

The present disclosure is direct to providing an optical sensor having high photoresponsivity and fast response speed and a method for manufacturing the same.

### Technical Solution

To solve the above-described problem, the present disclosure provides an optical sensor using ferroelectrics, including a substrate; a first type semiconductor stacked on the substrate; and a second type semiconductor in contact with the first type semiconductor to form a heterojunction structure, wherein at least one of the first type semiconductor or the second type semiconductor is ferroelectrics.

In an embodiment of the present disclosure, the first type semiconductor and the second type semiconductor are vertically deposited, and the first type semiconductor and the second type semiconductor are 2-dimensional (2D) semiconductor materials.

In an embodiment of the present disclosure, the first type is a p-type, the second type is an n-type, and the second type semiconductor has ferroelectricity.

In an embodiment of the present disclosure, the optical sensor using ferroelectrics further includes a first electrode in electrical communication with the first type semiconductor, and a second electrode in electrical communication with the second type semiconductor, the p-type 2D semiconductor material is a 2D material having a smaller bandgap than 3LWSe2 or WSe2, and the n-type 2D ferroelectric semiconductor material is α-In2Se3.

In an embodiment of the present disclosure, the optical sensor changes in photoresponsitivity depending on a direction in which a bias is applied to the optical sensor, and is determined according to a carrier polarization direction in the semiconductor rather than the ferroelectrics.

The present disclosure further provides a method for manufacturing an optical sensor using ferroelectrics, including stacking a first type semiconductor on a substrate; stacking a second type semiconductor on the first type semiconductor, wherein a heterojunction structure is formed by a contact between the first type semiconductor and the second type semiconductor; patterning a first electrode in electrical communication with the first type semiconductor on two sides of the first type semiconductor; and patterning a second electrode on the second type semiconductor and in contact with the second type semiconductor.

In an embodiment of the present disclosure, the first type semiconductor and the second type semiconductor are vertically deposited, the first type semiconductor and the second type semiconductor are 2D semiconductor materials, the first type is a p-type, the second type is an n-type, and the second type semiconductor has ferroelectricity.

### Advantageous Effects

According to the present disclosure, there is provided an optical sensor having a vertical heterojunction structure by an n-type 2-dimensional (2D) ferroelectric semiconductor and a p-type 2D semiconductor where vertical charge transfer occurs. Accordingly, the optical sensor according to the present disclosure has fast response speed, low dark current and broadband.

### BRIEF DESCRIPTION OF THE DRAWINGS

FIG. 1 is a diagram of an optical sensor including 2-dimensional ferroelectrics-semiconductor p-n heterojunction according to an embodiment of the present disclosure.

FIG. 2 is a diagram showing an optical sensor according to an embodiment of the present disclosure and its polarization state.

FIG. 3 is an energy diagram of a depletion layer when a first semiconductor is polarized by the application of an electric field and when the first semiconductor is unpolarized, in an optical sensor according to an embodiment of the present disclosure.

FIG. 4 is a diagram showing each step of a method for manufacturing an optical sensor device according to an embodiment of the present disclosure.

FIGS. 5 to 8 show analysis results of photoresponsivity, photodetectivity, broadband and response speed of an optical sensor manufactured according to an embodiment of the present disclosure.

### BEST MODE FOR CARRYING OUT THE INVENTION

Hereinafter, an optical sensor using 2-dimensional (2D) ferroelectric semiconductor according to the present disclosure and a method for manufacturing the same will be described in detail based on the accompanying drawings illustrating exemplary embodiments. For example, the terms or words used in the specification and the appended claims should not be construed as limited to general and dictionary meanings, but rather interpreted based on the meanings and concepts corresponding to technical spirit of the present disclosure on the basis of the principle that the inventor is allowed to define terms appropriately for the best explanation. Additionally, the embodiments proposed herein and illustrations in the accompanying drawings are exemplary embodiments of the present disclosure to describe the present disclosure but not intended to limit the technical spirit and thus there have been a variety of alternative equivalents and variations at the time that the application was filed.

To solve the above-described problem, the present disclosure provides an optical sensor having a heterojunction structure between ferroelectrics that maintains a polarization state irrespective of an external electric field and a 2D semiconductor material that is polarized by an external electric field. The adjustment of the polarization direction of ferroelectrics may reduce the dark current of the 2D channel material about 100 times than fresh state and enhance a depletion layer of a p-n junction, thereby improving the photoresponsivity in the visible region up to 13.7 times, and further, the photoresponsivity in the near-infrared region is about 100 times higher than that of the existing optical diode with the photoresponsivity of a few tens of mA/W, and thus it may be used as a near-infrared optical sensor.

The optical sensor according to an embodiment of the present disclosure has a basic structure having a depletion structure at vertical heterojunction by vertical deposition of ferroelectric 2D semiconductor and 2D semiconductor.

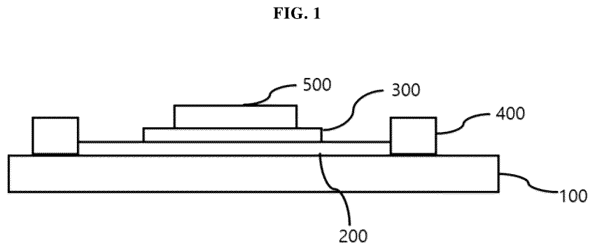

FIG. 1 is a diagram of an optical sensor including 2D ferroelectrics-semiconductor p-n heterojunction according to an embodiment of the present disclosure.

Referring to FIG. 1, the optical sensor according to an embodiment of the present disclosure includes a substrate 100; a first type semiconductor or p-type 2D semiconductor material 200 stacked on the substrate; and a second type semiconductor or n-type semiconductor material 300 stacked on the p-type 2D semiconductor material 200, wherein the second type semiconductor has ferroelectricity. Accordingly, the second type semiconductor maintains polarization (polling) state irrespective of whether or not an electric field is applied through electrodes, and the non-ferroelectric or first type semiconductor forms polarization state only when an electric field is applied.

The optical sensor according to an embodiment of the present disclosure includes a first electrode 300 in electrical communication with the first type semiconductor to apply an electric field to the first type semiconductor, and a second electrode 400 stacked on the second type semiconductor and in electrical communication with the second type semiconductor to detect the photocurrent.

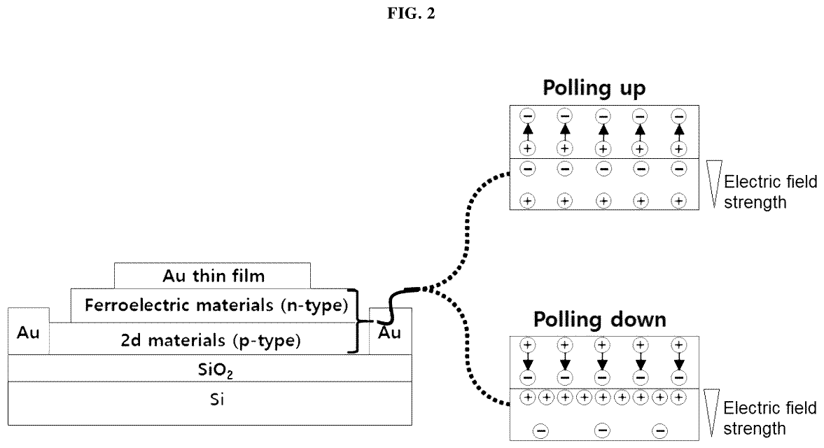

FIG. 2 is a diagram showing the optical sensor according to an embodiment of the present disclosure and its polarization state.

Referring to FIG. 2, the optical sensor according to an embodiment of the present disclosure changes in polarization state of the first type semiconductor that forms heterojunction with the ferroelectrics when the electric field is applied. Accordingly, the energy barrier configuration of the depletion layer at heterojunction changes.

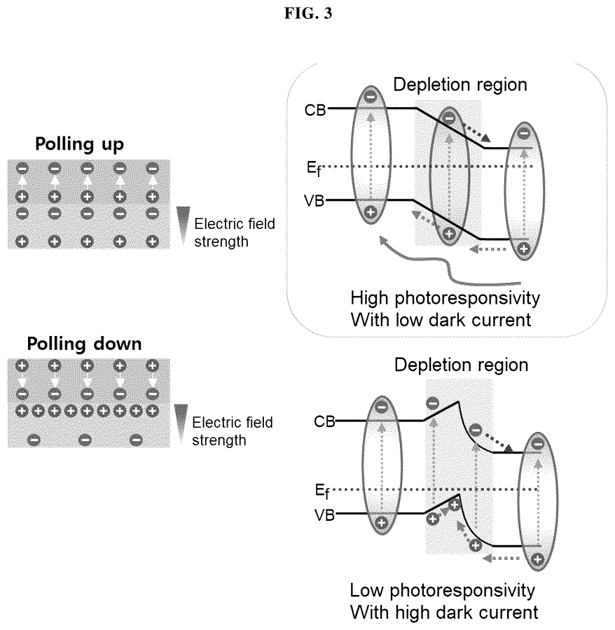

FIG. 3 is an energy diagram of the depletion layer when the first semiconductor is polarized by the application of the electric field and when the first semiconductor is unpolarized, in the optical sensor according to an embodiment of the present disclosure.

Referring to FIG. 3, when the polarization direction is an upward direction, the p-type 2D semiconductor depleted of holes that are majority carriers in the junction with the 2D ferroelectrics is enhanced. That is, as the built-in potential of p-n junction with the n-type 2D ferroelectric semiconductor is enhanced, the photoresponsivity increases, and the p-type 2D semiconductor that acts as channel suppresses the dark current flowing in the absence of light illumination, resulting in improved photodetectivity.

On the contrary, when the polarization direction is a downward direction, as holes that are majority carriers accumulate at the junction with the 2D ferroelectrics, the dark current increases, and electron-hole pair separation is sluggish, resulting in low photoresponsivity. That is, on the energy band diagram, electron-hole pairs are generated by light illumination but due to valleys that obstruct the diffusion to the channel region, they are not converted to photocurrent and gather in the valleys at the interface, and the electrons that are minority carriers cannot traverse the corresponding valleys, and this is the reason why the dark current is high.

### Example

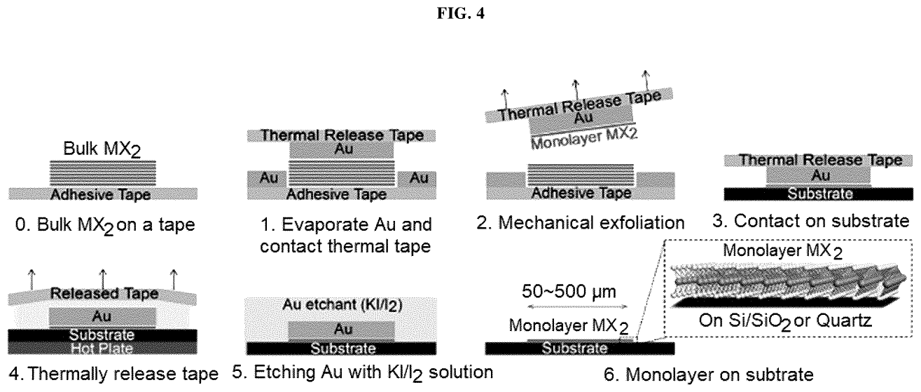

FIG. 4 is a diagram showing each step of a method for manufacturing the optical sensor device according to an embodiment of the present disclosure.

Referring to FIG. 4, flakes are obtained using an Au-mediated exfoliation method to obtain a p-type 2D semiconductor and an n-type 2D ferroelectric semiconductor of an area that is thin and as wide as possible. In an embodiment of the present disclosure, 3LWSe₂ is used as the p-type 2D semiconductor material, but any semiconductor material (for example, BP) having a smaller bandgap may be used, and this falls within the scope of the present disclosure. Additionally, α-In₂Se₃ (˜10 nm) is used as the n-type 2D ferroelectric semiconductor material, and the scope of the present disclosure is not limited to the material type used in this embodiment.

Subsequently, the obtained flakes are transferred onto PDMS through a PPC junction layer, followed by stamping onto a desired substrate and heating at the temperature of 90° C. at the same time, transferring to another Si/SiO2 substrate through a so-called pick-up transfer method, and patterning source/drain and gate electrodes using e-beam lithography (line width 3 um). Subsequently, device fabrication is completed through Cr/Au (5 nm/35 nm) deposition using a thermal evaporator.

In this embodiment, a 2D material having a smaller bandgap than WSe2, for example, 3LWSe₂, is used as the p-type 2D semiconductor material, and α-In₂S is used as the n-type 2D ferroelectric semiconductor material, but the scope of the present disclosure is not limited thereto.

Subsequently, the ferroelectrics of the fabricated device are polarized using DC bias. At high temperature, the existing random polarization direction is removed, and dc bias (polling up=+10 V, polling down=−10 V) is applied in the out-of-plane direction, and thus the polarization direction is determined as one direction. The applied dc bias value is a value of which the absolute value is higher than a voltage value used to determine the corresponding loop by measuring the PFM hysteresis loop.

### EXPERIMENTAL EXAMPLE

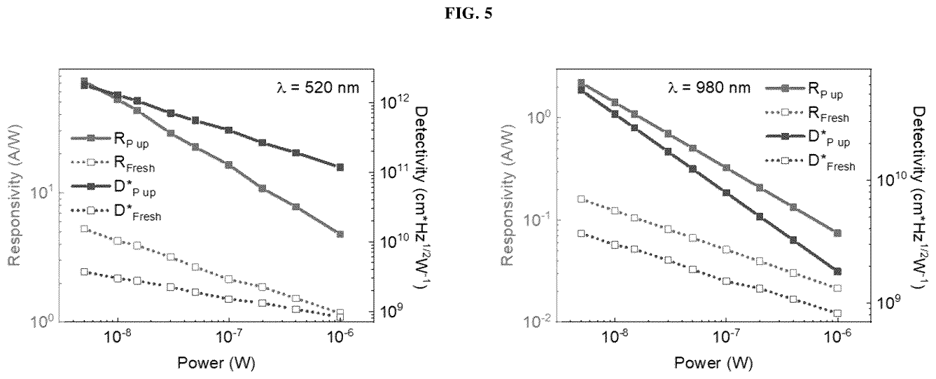

FIGS. 5 to 7 show analysis results of photoresponsivity, photodetectivity, broadband and response speed of the optical sensor manufactured according to an embodiment of the present disclosure.

Referring to FIG. 5, the results of FIG. 5 are obtained by extracting a graph of photoresponsivity and photodetectivity as a function of laser intensity, according to polarization and non-polarization and the wavelength (520 nm, 980 nm) of the laser used for illumination.

In the case of 520 nm, 5 nW, when the polarization direction is an upward direction, it can be seen that the photoresponsivity has 13.7 fold improvement from 5.26 A/W to 72.4 A/W, and the photodetectivity has 100 or more fold improvement from 3.6×109 Jones to 1.76×1012 Jones, compared to non-polarization (maximum value).

In the case of 980 nm, 5 nW, when the polarization direction is an upward direction, it can be seen that the photoresponsivity has 8.5 fold improvement from 0.16 A/W to 2.21 A/W, and the photodetectivity has about 8 fold improvement from 3.69×109 Jones to 5.37×1010 Jones, compared to non-polarization.

Additionally, it can be seen that the photoresponsivity at 980 nm in the NIR region is 100 times or more higher than those of optical detectors with the photoresponsivity of a few tens of mA/W in the NIR region.

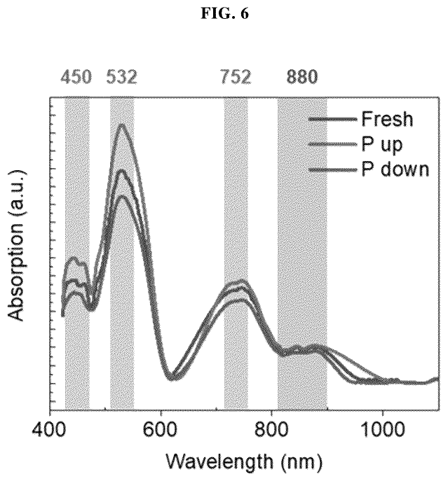

FIG. 6 shows the absorption spectrum of the channel region.

Referring to FIG. 6, a blue semitransparent region is a peak corresponding to the p-type 2D semiconductor material, and a red semitransparent region is a peak corresponding to the n-type 2D ferroelectric semiconductor material. When the polarization direction is an upward direction, the absorption wavelength range increases compared to non-polarization (960 nm→1020 nm, 7%). This result signifies an increase in wavelength region that the optical detector detects. The n-type 2D ferroelectric semiconductor increases in density of state in the material itself by the effect of strain induced by polarization, and eventually the radiative recombination increases, and as a result, the detection region expands.

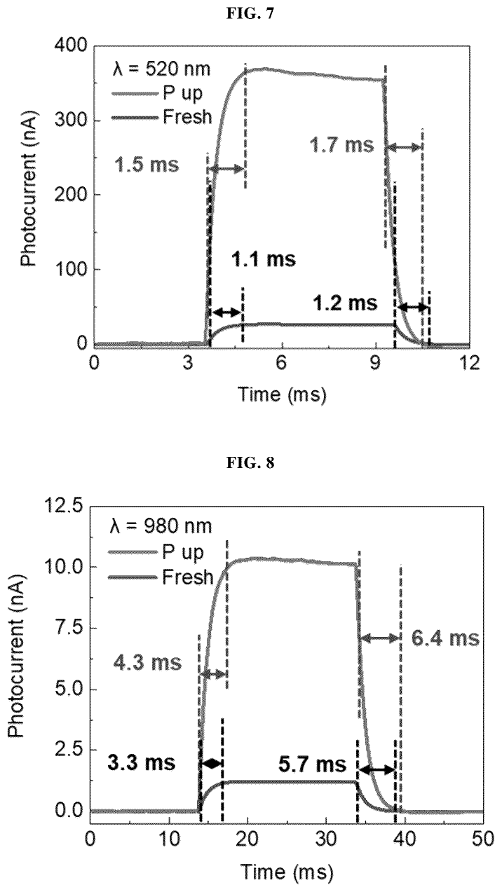

FIG. 7 shows the measured photoresponse time (the response time of the optical device) according to polarization and non-polarization when the wavelength of the laser is 520 nm. When polarized, the response time slightly increases, and this is because carrier movement in the p-type 2D semiconductor in which response occurs primarily at 520 nm is impeded by the polarization of the ferroelectrics.

FIG. 8 is a photoresponse time graph in the NIR region.

Referring to FIG. 8, when extracting the response time in the NIR region, it is found that the value is slightly higher than that of the visible region, and since the n-type 2D ferroelectrics respond primarily in the NIR region, it seems to be due to a time delay caused by the migration to the channel region across the interface.

As described above, the present disclosure provides an optical detection device using the 2D materials as the channel material and the ferroelectric material. In this case, the 2D materials have a higher light absorption rate than bulk materials such as silicon and can obtain high photoresponsivity due to high mobility, and in addition to these advantages, the present disclosure using the ferroelectric 2D material has a yield advantage since the characteristics are stably exhibited at the thickness of at least 2 nm (two layers) by solving the large space occupying problem of the existing thin-film type ferroelectric materials that require the thickness of 100 nm or more to stably exhibit the characteristics.

Additionally, the 2D materials have good interfacial characteristics at the junction of the two materials due to the absence of dangling bonds, and especially, since the two materials used has the same hexagonal lattice structure and are equally Se, they have the outstanding characteristics.

As described above, the optical sensor according to an embodiment of the present disclosure includes the p-n heterojunction between the n-type 2D ferroelectric semiconductor and the p-type 2D semiconductor material where vertical charge transfer occurs, wherein the adjustment of the polarization direction of the ferroelectrics reduces the dark current of the 2D channel material about 100 times compared to the fresh state and enhances the depletion layer of the p-n junction, thereby improving the photoresponsivity in the visible region up to 13.7 times.

Additionally, the photoresponsivity in the near-infrared region is also about 100 times higher than that of the existing optical diode with the photoresponsivity of a few tens of mA/W, so it is confirmed as a competitive near-infrared optical sensor. Additionally, it is confirmed that the p-n vertical junction structure generates excited hole carriers in the ferroelectrics, and besides, generates, in the depletion layer, fast charge carriers having an ms level response speed that is about 1000 times lower than the existing optical transistor structure, and the broadband is adjusted according to the polarization direction and expanded to the near-infrared region of 1020 nm. Additionally, it is confirmed that the polarization method using DC bias stably maintains the polarization state up to 18 hours, and it first proposes the possibility of the vertical p-n junction structure of 2D ferroelectric semiconductor-2D semiconductor as a visible-near-infrared optical sensor having next-generation high performance.

1. An optical sensor using ferroelectrics, comprising:
a substrate;
a first type semiconductor stacked on the substrate; and
a second type semiconductor in contact with the first type semiconductor to form a heterojunction structure,
wherein at least one of the first type semiconductor or the second type semiconductor is ferroelectrics.

2. The optical sensor using ferroelectrics of claim 1, wherein the first type semiconductor and the second type semiconductor are vertically deposited, and the first type semiconductor and the second type semiconductor are 2-dimensional (2D) semiconductor materials.

3. The optical sensor using ferroelectrics of claim 1, wherein the first type is a p-type, the second type is an n-type, and the second type semiconductor has ferroelectricity.

4. The optical sensor using ferroelectrics of claim 1, further comprising:
a first electrode in electrical communication with the first type semiconductor, and a second electrode in electrical communication with the second type semiconductor.

5. The optical sensor using ferroelectrics of claim 3, wherein the p-type 2D semiconductor material is a 2D material having a smaller bandgap than 3LWSe₂ or WSe₂, and the n-type 2D ferroelectric semiconductor material is α-In₂Se₃.

6. The optical sensor using ferroelectrics of claim 1, wherein the optical sensor changes in photoresponsivity depending on a direction in which a bias is applied to the optical sensor, and is determined according to a carrier polarization direction in the semiconductor rather than the ferroelectrics.

7. A method for manufacturing an optical sensor using ferroelectrics, comprising:
stacking a first type semiconductor on a substrate;
stacking a second type semiconductor on the first type semiconductor, wherein a heterojunction structure is formed by a contact between the first type semiconductor and the second type semiconductor;
patterning a first electrode in electrical communication with the first type semiconductor on two sides of the first type semiconductor; and
patterning a second electrode on the second type semiconductor and in contact with the second type semiconductor.

8. The method for manufacturing an optical sensor using ferroelectrics of claim 7, wherein the first type semiconductor and the second type semiconductor are vertically deposited, and the first type semiconductor and the second type semiconductor are 2-dimensional semiconductor materials.

9. The method for manufacturing an optical sensor using ferroelectrics of claim 8, wherein the first type is a p-type, the second type is an n-type, and the second type semiconductor has ferroelectricity.
